(19) United States
(12) Patent Application Publication
(10) Pub. No.: US 2008/0272473 A1
(43) Pub. Date: Nov. 6, 2008

(54) OPTICAL DEVICE AND METHOD OF MANUFACTURING THE SAME

(75) Inventors: Katsuyoshi Matsumoto, Osaka (JP); Tetsushi NISHIO, Kyoto (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 12/105,388

(22) Filed: Apr. 18, 2008

(30) Foreign Application Priority Data
May 1, 2007 (JP) 2007-120432

(51) Int. Cl. H01L 23/58; H01L 21/56

(52) U.S. Cl. 257/680; 438/116; 257/E23.002; 257/E21.502

(57) ABSTRACT

The present invention provides an optical device (2) including: a substrate (1) having a resin base (11) provided with an opening, a plurality of conductors (13) embedded in the resin base (11) such that at least parts of the plurality of conductors (13) are exposed on a lower face of the resin base (11) as electrode terminals, and a transparent member (12) fitted into the opening of the resin base (11); and an optical element (31) having an optical region (32) on an upper face thereof and which is mounted to a lower face of the substrate (11) so that the optical region (32) opposes the opening of the resin base (11), wherein the substrate (11) has a rectangular tabular shape whose thickness is substantially even.

### FIELD OF THE INVENTION

The present invention relates to an optical device and a method of manufacturing the same.

### BACKGROUND OF THE INVENTION

Recently, in response to demands for reductions in size, thickness and weight as well as for higher functionality in electronic equipment, the mainstream of semiconductor device implementation has been shifting from conventional package implementation to flip chip implementation of a bare chip or a CSP (Chip Size Package). With an optical device, a reduction in the thickness of the device is achieved not only by a flip chip implementation of an optical element on a base on which a conductor is arranged, but also by employing a structure in which a transparent member is embedded into the base in order to protect the optical element.

FIG. 5 shows an example of such an optical device. On one face of a flat base 11 (hereinafter referred to as a substrate 11) provided with an opening and a conductor, an optical element 31 is flip chip-implemented so that a light receiving region 32 thereof faces the opening. A transparent member 12 is fitted into and bonded by an adhesive 38 in a recess 37 formed at the opening so as to have a difference in level with respect to the other face of the substrate 11 (for example, Japanese Patent Laid-Open No. 2005-235902). There is also an optical device in which an inner face of an opening of a substrate is tapered and a transparent member provided with a corresponding taper on an outer face thereof is embedded into the substrate (for example, Japanese Patent Laid-Open No. 2005-217337).

However, such optical devices obviously require a process for fastening the transparent member using an adhesive. In addition, since the substrate itself is thin with a typical thickness of around 0.5 to 0.6 mm, the thickness of the transparent member must also be significantly reduced to set the upper face of the transparent member at a position lower than the upper face of the substrate in order to make the device sufficiently thin. Consequently, the strength of the transparent member is reduced, handling of the transparent member becomes difficult and, when a glass plate is used as the transparent member, the price thereof also increases. Optical devices with a tapered substrate opening and a tapered transparent member further require a process for providing such tapers. Obviously, an additional process results in higher cost.

Alternatively, there is a method in which a transparent member is obtained by integrally molding an optically-transparent material to an opening of a substrate (for example, Japanese Patent Laid-Open No. 2005-136484). However, for example, in a case where a resin molding method using a metal mold is employed, an inlet of the metal mold must inevitably be disposed at any of positions that become the upper and lower faces of the transparent member. As a result, it is difficult to ensure flatness of the entire upper and lower faces and a process for surface polishing or the like is required. In a case where a method is employed in which liquid resin is poured from above in a state where a substrate is placed on top of a tape member and leveled without using a metal mold, flatness is determined by the face tension of the liquid resin. Consequently, since it is difficult to ensure flatness to the vicinity of an edge of an opening, a process for polishing the face or the like is similarly required in this case. Although the need for a surface polishing process is conceivably eliminated by sufficiently expanding the opening of the substrate in comparison to an optical region of an optical element so as to avoid optical influences from a non-smooth region occurring at an edge of the transparent member, this arrangement results in an increase in substrate size and, in turn, an increase in the size of an optical device.

### DISCLOSURE OF THE INVENTION

The present invention is made in consideration of the disadvantages described above, and an object of the invention is to provide a thin substrate that is readily manufactured and which includes a smooth and strong translucent member, and a thin optical device using the substrate.

In order to achieve the above-described object, the present invention provides an optical device including: a substrate having a resin base provided with an opening, a plurality of conductors embedded in the resin base such that at least parts of the plurality of conductors are exposed on a lower face of the resin base as electrode terminals, and a transparent member fitted into the opening of the resin base; and an optical element having an optical region on an upper face thereof and which is mounted to a lower face of the substrate such that the optical region opposes the opening of the resin base, wherein the substrate has a rectangular tabular shape whose thickness is substantially even.

In addition, the present invention provides a method of manufacturing an optical device including the steps of: mounting a transparent member on a supporting member; mounting a conductor on the supporting member; holding a lower face of the supporting member and an upper face of the transparent member with a metal mold and performing resin molding on the transparent member and the conductors; and connecting an optical element having an optical region on an upper face thereof to a lower face of the conductors so that the transparent member and the optical regions oppose each other.

Furthermore, the present invention provides a method of manufacturing an optical device including the steps of: mounting a plurality of transparent members on a supporting member; mounting a conductor extending from the vicinity of respective outer peripheries of the plurality of transparent members to an outer side on the supporting member on the respective outer peripheries of the plurality of transparent members; holding a lower face of the supporting member and upper faces of the plurality of transparent members with a metal mold and performing resin molding on the plurality of transparent members and the conductors; and connecting a plurality of optical elements having an optical region on an upper face thereof to a lower face of the conductors so that the respective optical regions and the transparent members oppose each other.

By preparing a transparent member whose upper and lower faces are both flat, the above-described optical device is capable of ensuring flatness of the upper and lower faces of the transparent member even after the same is incorporated into the substrate. Since the transparent member can be arranged so as to have the same thickness as a wiring portion (resin+conductor), the strength of the transparent member can be ensured and easier handling can be achieved. The thickness of the entire substrate also need not be thicker than thicknesses respectively required by the wiring portion and the transparent member, thereby enabling a reduction in the thickness of the entire substrate. Consequently, a thin optical device can be realized.

When manufacturing substrates, since resin molding is performed so as to embed the transparent member and the conductors, a process for fastening the transparent member using an adhesive is no longer required. As a result, manufacturing can be performed in a simple and inexpensive manner. Employing a method in which a plurality of substrates is integrally formed and subsequently separated enables manufacturing to be performed even more simply and inexpensively.

Consequently, an optical device is realized which has, for example, the characteristics described below. The thicknesses of the resin base and the transparent member are substantially the same. Both upper and lower faces of the transparent member are substantially flat. The thickness of the substrate is around 300 μm to 500 μm. The transparent member and the resin base are integrally resin-molded.

The optical element can be connected to the electrode terminal of the conductor via a bump. The optical element may include either one of or both a light receiving element portion and a light emitting element portion. A transparent adhesive may be provided between the optical region of the optical element and the transparent member of the substrate.

The transparent member may either be composed of any one material among optical glass, quartz, crystal and optical resin, or be constituted by combining a plurality of structures composed of any one material among the same. The surface of the transparent member is preferably covered with antireflective coating.

### BRIEF DESCRIPTION OF THE DRAWINGS

FIG. 1 is a diagram showing a configuration of a substrate used in an optical device according to the present invention;

FIG. 2 is a cross sectional view describing a method of manufacturing the substrate shown in FIG. 1;

FIG. 3 is a cross sectional view showing a configuration of the optical device according to the present invention;

FIG. 4 is a cross sectional view of a camera module using the optical device shown in FIG. 3; and

FIG. 5 is a cross sectional view of a conventional optical device.

### DESCRIPTION OF THE EMBODIMENTS

An embodiment of the present invention will now be described in detail with reference to the drawings. Thicknesses, lengths and the like of the respective members depicted in the drawings are provided for better understanding and may differ from actual shapes.

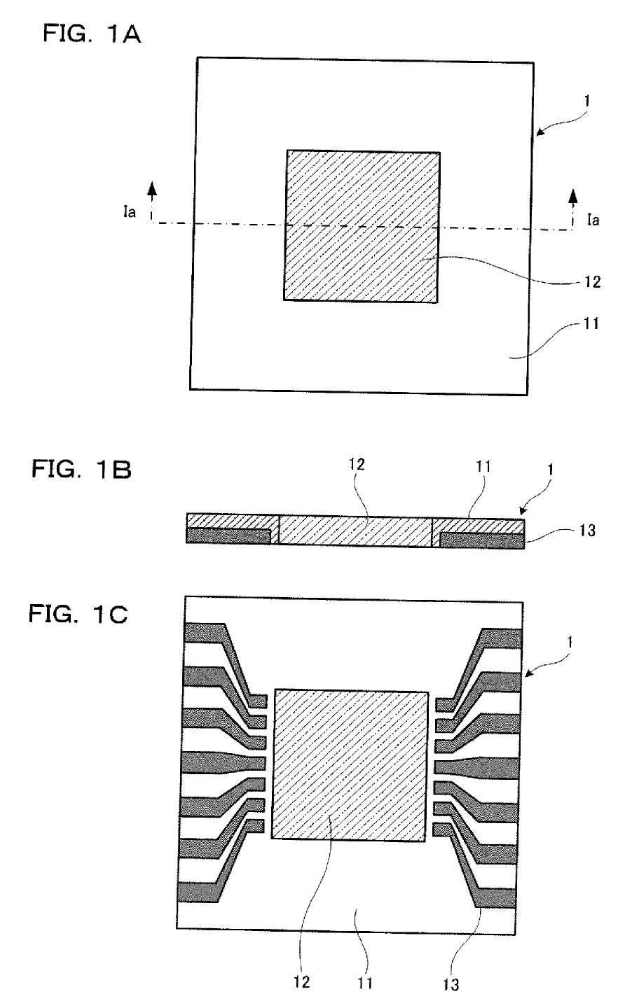

FIG. 1(A) is a top view of a substrate used in an optical device according to the present invention; FIG. 1(B) is a cross sectional diagram of the substrate taken along the line Ia-Ia of FIG. 1(A); and FIG. 1(C) is a bottom view of the substrate.

A substrate 1 is provided for mounting thereon an optical element (to be described later) having an optical region and an electrode terminal on one face thereof. The substrate 1 has a rectangular tabular shape whose thickness is substantially even and is composed of a resin base 11, a transparent member 12 and a plurality of conductors 13. The resin base 11 is formed of insulating material including a plastic resin such as epoxy resin.

The transparent member 12 is for protecting the optical region of the optical element and is embedded into a central portion of the resin base 11 having a uniform thickness so that both faces of the transparent member 12 are exposed. The top and bottom faces of the transparent member 12 are parallel to each other and form an optical flat face with a flatness satisfying an intended optics application. The thickness of the transparent member 12 is, for example, between 300 μm (inclusive) and 500 μm (inclusive).

For the transparent member 12, for example, optical glass, quartz, crystal, optical transparent resin or the like is used singularly or made into a plurality of structures that are integrally combined for use. When combining materials, an advantage can be achieved in that features of the respective materials are combined. For example, in the case of glass+crystal, surface hardness can be ensured and a filter effect with respect to the long-wavelength region may be achieved.

The plurality of conductors 13 extend from the vicinity of an outer periphery of the transparent member 12 up to an outer edge of the resin base 11 so as to have electrode terminals disposed opposing the electrode terminal of the optical element, and are embedded into the resin base 11 so that the surfaces of the electrode terminals are exposed. The conductors 13 are made from material similar to material used in so-called metal leads such as Cu alloy, 42 alloy (Fe—Ni 42 alloy) or the like. The thickness of the conductors 13 is, for example, between 100 μm (inclusive) and 300 μm (inclusive), and preferably around 200 μm.

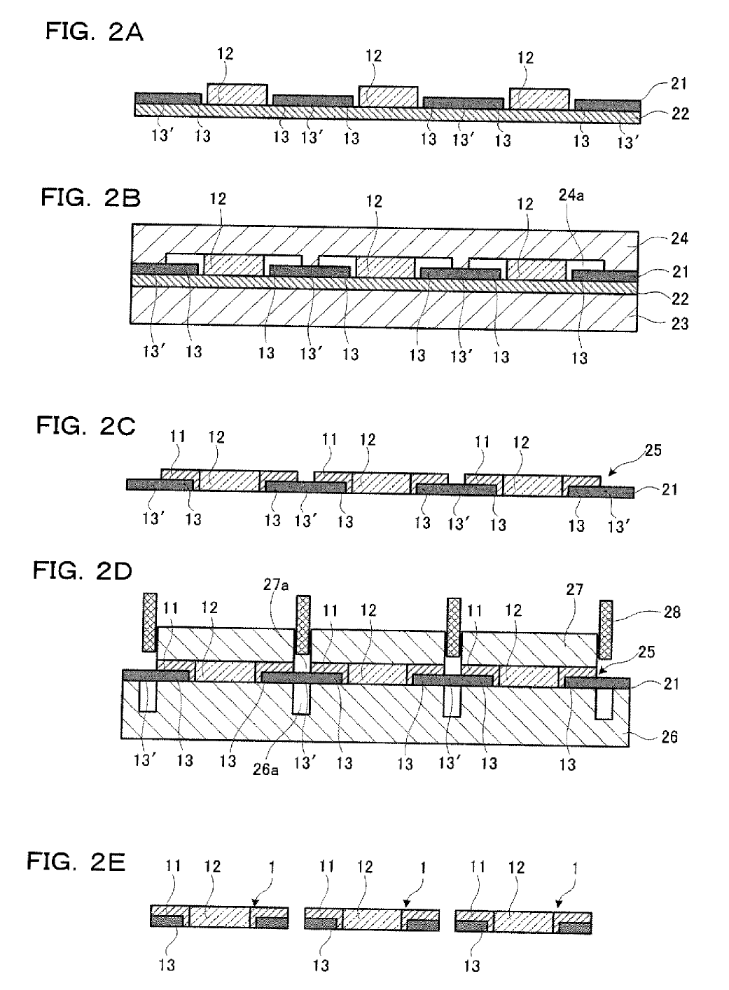

A method of manufacturing the substrate 1 will be described with reference to FIG. 2.

First, as shown in FIG. 2(A), a plurality of transparent members 12 are mounted on a tape member 22 at predetermined intervals. A thin metal plate 21 (a so-called lead frame) is also mounted on the tape member 22. The thin metal plate 21 includes a plurality of conductors 13 arranged in a predetermined array (quantity, size) with respect to each transparent member 12, and joining sections 131 (respectively extending in the depth-wise direction of the diagram and mutually joined by an outer frame portion, not shown) which join the plurality of conductors 13.

As shown in FIG. 2(B), a lower metal mold 23 and an upper metal mold 24 are disposed so as to oppose each other across the tape member 22 on which are mounted the above-described plurality of transparent members 12 and the thin metal plate 21. The upper metal mold 24 forms a space corresponding to a single substrate 1 and is provided with a plurality of recesses 24a that hold the transparent members 12 by inner bottom faces thereof. Cavities formed by the recesses 24a are filled with a liquid resin that is subsequently hardened.

As shown in FIG. 2(C), the lower metal mold 23 and the upper metal mold 24 are opened to remove a formed resin compact 25 and to peel off the tape member 22. The resin compact 25 is embedded such that the conductors 13 and the joining sections 13′ are positioned on a lower face of the compact and the transparent members 12 penetrate the compact in a thickness-wise direction thereof.

As shown in FIG. 2(D), the resin compact 25 is held between a receiving metal mold 26 and a holding metal mold 27, and the joining sections 13′ of the thin metal plate 21 are stamped out by punching positions corresponding to respective gap portions 26a and 27a by a pressing metal mold 28.

Subsequently, the receiving metal mold 26 and the holding metal mold 27 are opened to retrieve a plurality of singulated substrates 1 as shown in FIG. 2(E).

As may be understood from the processes described above, by providing the substrate 1 with the transparent members 12 whose upper and lower faces are both flat, the flatness of the upper and lower faces of the transparent members 12 after incorporated into the substrate 1 can also be easily ensured. The thickness of the transparent members 12 need only be substantially the same as the thickness of a wiring portion (resin+conductors 13) of the substrate 1. Consequently, strength and easy handling are ensured and selection of inexpensive material is enabled. The thickness of the entire substrate 1 also need not be thicker than the thicknesses respectively required by the wiring portion and the transparent members 12 and may be reduced down to within 300 μm to 500 μm.

Since the described method involves molding the resin base 11 integrally with the transparent members 12 and the conductors 13 within the lower metal mold 23 and the upper metal mold 24, a process for mounting the transparent members 12 via an adhesive, as is conventional, is no longer required. Consequently, a reduction in manufacturing cost can be achieved. Since the method also involves continuously molding a plurality of substrates 1 and subsequently separating the plurality of substrates 1 into individual pieces, a further reduction in manufacturing cost can be achieved.

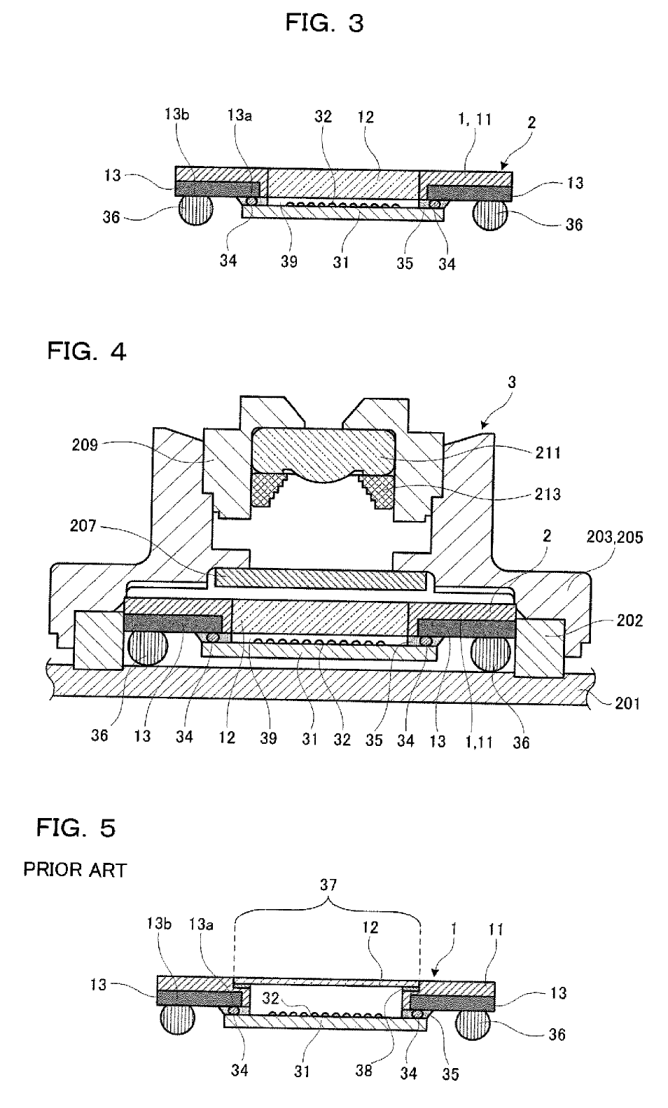

FIG. 3 is a cross sectional view showing a configuration of an optical device according to the present invention using the substrate shown in FIG. 1.

An optical device 2 is composed of a substrate 1 having an optical element 31 flip chip-implemented on a face thereof on which conductors 13 are formed. The substrate 1 and the optical element 31 are selected such that a transparent member 12 has a planar shape larger than at least an optical region 32 of the optical element 31. The optical element 31 is positioned so as to secure a light path above a light receiving region 32 through the transparent member 12, and is flip chip-connected to internal terminals (portions proximal to the transparent member 12) 13a of the conductors 13 via bumps 34 formed on an electrode pad (not shown) of the optical element 31.

A gap between an electrode region of the optical element 31 and a region of the substrate 1 opposing the electrode region is filled with a molding resin 35. A hollow space 39 is formed at a center portion of the gap at a position between the optical element 31 and the transparent member 12. A solder ball 36 for connecting to an electrode on an external substrate is mounted on an external terminal 13b of each conductor 13 (a portion of each conductor 13 disposed on a peripheral portion of the substrate).

With the optical device 2, the use of the substrate 1 whose thickness is reduced as described above realizes a thin optical device 2 that can be manufactured inexpensively. In addition, disposing the molding resin 35 prevents disconnection when stress due to an external force or heat is applied to the bumps 34; providing the sealed hollow space 39 above the light receiving region 32 of the optical element 31 prevents contamination of the light receiving region 32 after the optical device 2 is assembled; and unwanted reflection and incidence of light can be suppressed.

Similar advantages may be achieved by disposing a transparent adhesive at the portion arranged as the hollow space 39 in FIG. 3. Although not shown, antireflective coating can also be provided on the front face, all faces, or a portion of the faces of the transparent member 12. Providing antireflective coating on the upper and lower faces of the transparent member 12 reduces reflection of transmitted light and increases transmitted light efficiency. Providing antireflective coating on a lateral face of the transparent member 12 reduces light reflected by the face and, in turn, reduces unwanted light such as a flare which reaches the optical element.

The light receiving region 32 depicted on the optical element 31 is a region at which is formed a light receiving element portion that detects light. As the light receiving element portion, for example, an image sensor such as a CMOS sensor or a CCD sensor is formed. A light emitting region at which is formed a light emitting element portion such as a light emitting laser or a light emitting diode may be formed on the optical element 31 instead of the light receiving region 32. It is also possible to provide both a light receiving region and a light emitting region.

FIG. 4 is a cross sectional view showing a configuration of a camera module mounted with the optical device 2 shown in FIG. 3. A camera module 3 includes the optical device 2, a substrate 201 on which the optical device 2 is mounted, positioning spacers 202 disposed on the substrate 201 and around the optical device 2, and a lens tube 203 fixed above the substrate 201 with the positioning spacers 202 positioned therebetween.

The lens tube 203 includes a lens tube base 205, a glass plate 207 and a lens housing portion 209 disposed inside the lens tube base 205, and a lens 211 and a lens holder 213 disposed inside the lens housing portion 209. The glass plate 207 and the lens 211 are held at positions above the light receiving region 32 of the optical element 31 of the optical device 2.

With the camera module 3, the use of the optical device 2 whose thickness is reduced as described above enables the height of the camera module 3 to be reduced and manufacturing of the camera module 3 to be performed inexpensively. The camera module 3 as referred to herein is a digital camera, a surveillance camera, a video camera, a mobile phone camera or the like. The optical element 31 used in the optical device 2 has a light receiving element portion such as an image sensor.

As described above, according to the present invention, since a substrate is configured by embedding a conductor and a transparent member into a resin base such that both faces of the transparent member and a surface of an electrode terminal of the conductor are exposed, a reduction in the thickness of the substrate and a reduction in cost can be achieved while ensuring strength, easy handling and smoothness of the transparent member.

Assembling an optical device using this substrate reduces the thickness of the optical device and ensures high reliability while protecting an optical region of an optical element.

Specific examples of equipment mounted with such an optical device include a digital camera, a video camera, a mobile phone camera, a surveillance camera, a vehicle-mounted camera, a camera for medical applications, a broadcast camera, a Web camera, a camera for a TV telephone, and a camera for a game console, as well as an optical pickup such as an optical mouse, a DVD drive and a CD drive.

What is claimed is:

1. An optical device comprising:
a substrate having a resin base provided with an opening, a plurality of conductors embedded in the resin base such that at least parts of the plurality of conductors are exposed on a lower face of the resin base as electrode terminals, and a transparent member fitted into the opening of the resin base; and
an optical element having an optical region on an upper face thereof and which is mounted to a lower face of the substrate so that the optical region opposes the opening of the resin base,
wherein the substrate has a rectangular tabular shape whose thickness is substantially even.

2. The optical device according to claim 1, wherein thicknesses of the resin base and the transparent member are substantially equal.

3. The optical device according to claim 1, wherein both upper and lower faces of the transparent member are substantially flat.

4. The optical device according to claim 1, wherein a thickness of the substrate is around 300 μm to 500 μm.

5. The optical device according to claim 1, wherein the optical element is connected to the electrode terminals of the conductors via bumps.

6. The optical device according to claim 1, wherein the transparent member and the resin base are integrally resin-molded.

7. The optical device according to claim 1, wherein the transparent member is made of any one material among optical glass, quartz, crystal and optical resin.

8. The optical device according to claim 1, wherein the transparent member is constituted by combining a plurality of structures composed of any one material among optical glass, quartz, crystal and optical resin.

9. The optical device according to claim 1, wherein the optical element has either one of or both a light receiving element portion and a light emitting element portion.

10. The optical device according to claim 1, further comprising a transparent adhesive between the optical region of the optical element and the transparent member of the substrate.

11. The optical device according to claim 1, wherein the transparent member is provided with antireflective coating on a surface thereof.

12. A method of manufacturing an optical device comprising the steps of:
mounting a transparent member on a supporting member;
mounting a conductor on the supporting member;
holding a lower face of the supporting member and an upper face of the transparent member with a metal mold and performing resin molding on the transparent member and the conductors; and
connecting an optical element having an optical region on an upper face thereof to a lower face of the conductors so that the transparent member and the optical region oppose each other.

13. A method of manufacturing an optical device comprising the steps of:
mounting a plurality of transparent members on a supporting member;
mounting a conductor extending from a vicinity of respective outer peripheries of the plurality of transparent members to an outer side on the supporting member on the respective outer peripheries of the plurality of transparent members;
holding a lower face of the supporting member and upper faces of the plurality of transparent members with a metal mold and performing resin molding on the plurality of transparent members and the conductors; and
connecting a plurality of optical elements having an optical region on an upper face thereof to a lower face of the conductors so that the respective optical regions and the transparent members oppose each other.
